(19) United States
(12) Patent Application Publication
(10) Pub. No.: US 2005/0269612 A1
(43) Pub. Date: Dec. 8, 2005

(54) Solid-state component based on current-induced magnetization reversal

(75) Inventors: E. James Torok, Shoreview, MN (US); David Fleming, Minnetonka, MN (US); Richard Spitzer, Berkeley, CA (US)

Correspondence Address: BEYER WEAVER & THOMAS LLP, P.O. BOX 70250, OAKLAND, CA, 94612-0250, US

(73) Assignee: Integrated Magnetoelectronics

(21) Appl. No.: 11/126,950

(22) Filed: May 10, 2005

Related U.S. Application Data
(60) Provisional application No. 60/570,216, filed on May 11, 2004.

(51) Int. Cl. G01R 33/02; H01L 29/76; H01L 29/94; H01L 31/062; H01L 31/113; H01L 31/119

(52) U.S. Cl. 257/295; 324/252

(57) ABSTRACT

A solid-state component including a network of multi-layer structures is described. Each multi-layer structure exhibits magnetoresistance and has magnetization vectors associated therewith which are operable to be switched at least in part by current-induced magnetization reversal. The solid-state component generates an output signal when the network of multi-layer structures is resistively imbalanced. The output signal corresponds to output nodes in the network and is a function of an input signal applied at input nodes in the network.

### RELATED APPLICATION DATA

The present application claims priority under 35 U.S.C. 119(e) to U.S. Provisional Patent Application No. 60/570,216 for SOLID-STATE COMPONENT filed on May 11, 2004 (Attorney Docket No. IMECP021P), the entire disclosure of which is incorporated herein by reference for all purposes.

### BACKGROUND OF THE INVENTION

The present invention relates to solid-state components which may be employed to construct a wide range of circuits and systems. More specifically, the present invention provides a highly versatile solid-state component the operation of which relies, at least in part, on the phenomenon known as current-induced magnetization reversal in materials exhibiting magnetoresistance.

A versatile solid-state component known as a “transpinnor” is described in U.S. Pat. No. 5,929,636 and U.S. Pat. No. 6,031,273, the entire disclosures of both of which are incorporated herein by reference for all purposes. Specific implementations of the transpinnor described in those patents include a bridge network of GMR thin-film elements connected electrically to one another and to power terminals, and one or more current-carrying input lines (e.g., striplines) positioned adjacent, and electrically insulated from, the GMR elements.

The GMR elements in some transpinnor implementations include two or more magnetic layers separated by a non-magnetic metal layer. The magnetic layers have well separated switching characteristics. A hard layer, i.e., a magnetic layer characterized by a higher coercivity, switches at relatively higher field strengths. A soft layer, i.e., a magnetic layer characterized by a lower coercivity, switches at relatively lower field strengths. The magnetization vector in the soft layer can be reoriented without disturbing the hard layer to create parallel and antiparallel alignments of the associated magnetizations.

The resistance, R, of these elements depends on the relative orientation of the magnetizations of the magnetic layers according to the relationship,
R=R₀+½R_{↑↑}(1+m₁·m₂)+½R_{↑↓}(1−m₁·m₂), (1)
where R₀ is the resistance component due to spin-independent scattering of charge carriers, R↑↑ (R↑↓) is the spin-dependent resistance component for parallel (antiparallel) relative orientation of the magnetizations in the two layers with R↑↓>R↑↑, mᵢ is a unit vector of magnetization in layer i, and m₁·m₂ is their scalar product.

When the magnetizations of the hard and soft layers are aligned parallel the resistance of the GMR film is minimum, Rₘᵢₙ; when antiparallel, the resistance is maximum, Rₘₐₓ. Intermediate alignments result in intermediate values of GMR resistance. The decimal value of GMR is given by
gmr=(Rₘₐₓ−Rₘᵢₙ)/Rₘᵢₙ=(R_{↑↓}−R_{↑↑})/ (R₀+R_{↑↑}), (2)

The various magnetic layers in a GMR film are separated by metallic non-magnetic layers. The thickness of these intermediate non-magnetic metal layers is important in controlling the strength of the magnetic interaction between the magnetic layers. This interaction can promote alignment or antialignment of these layers.

In the GMR transpinnor described in the above-referenced patents, the magnetic field from current-carrying striplines is used to switch the magnetization of the soft layers in the GMR films. Power-in and power-out leads provide a current which flows in the plane of the GMR element thin films, i.e., CIP. When the transpinnor is resistively balanced, its output remains zero even with power current applied to it. A stripline current above the threshold for reversing the magnetization of a soft layer in one or more of the GMR films can change the film resistance, unbalance the transpinnor, and result in a non-zero output signal.

Transpinnors are highly versatile components which are capable of gain and can be operated in analog or digital modes. Choices of design characteristics include the configuration of striplines relative to the GMR elements, input-current polarities, direction of magnetic field produced by the stripline current relative to the magnetization of the switching layers in these films, and initial transpinnor state, i.e. direction of the hard-layer magnetization. Appropriate manipulation of these design characteristics results in such a wide range of functionalities and operational modes that the transpinnor may be employed to implement virtually any type of conventional circuit component.

Given the advantages associated with transpinnor-based circuitry and electronics based on various magnetoresistive effects, it is desirable to continue to improve and optimize such technologies.

### SUMMARY OF THE INVENTION

According to a specific embodiment of the present invention, a solid-state component including a network of multi-layer structures is provided. Each multi-layer structure exhibits magnetoresistance and has magnetization vectors associated therewith which are operable to be switched at least in part by current-induced magnetization reversal. The solid-state component generates an output signal when the network of multi-layer structures is resistively imbalanced. The output signal corresponds to output nodes in the network and is a function of an input signal applied at input nodes in the network.

According to another specific embodiment of the present invention, a solid-state component comprising a plurality of multi-layer structures configured in a bridge network is provided. First and second opposing nodes of the network are an input. Third and fourth opposing nodes of the network are an output. Each of the multi-layer structures exhibits magnetoresistance and is operable to have associated magnetization vectors at least partially switched by spin-transfer switching in response to current applied via the input, the current being perpendicular to the layers of the multi-layer structures. The solid-state component generates an output signal at the output when the network of multi-layer structures is resistively imbalanced. The output signal is representative of the current applied at the input.

A further understanding of the nature and advantages of the present invention may be realized by reference to the remaining portions of the specification and the drawings.

### BRIEF DESCRIPTION OF THE DRAWINGS

FIG. 1 is a graph illustrating manipulation of a spin-transfer switching threshold.

FIGS. 2A and 2B are simplified diagrams of thin-film structures for use in transpinnors designed according to specific embodiments of the invention.

FIG. 3 is a simplified diagram of a transpinnor designed according to a specific embodiment of the invention.

FIG. 4 is a simplified diagram of a transpinnor designed according to another specific embodiment of the invention.

FIG. 5 is a simplified diagram of a memory array designed using transpinnors designed according to the invention.

FIG. 6 is a simplified diagram of a system-on-a-chip designed using transpinnors designed according to the invention.

### DETAILED DESCRIPTION OF SPECIFIC EMBODIMENTS

Reference will now be made in detail to specific embodiments of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims. In the following description, specific details are set forth in order to provide a thorough understanding of the present invention. The present invention may be practiced without some or all of these specific details. In addition, well known features may not have been described in detail to avoid unnecessarily obscuring the invention.

The present invention provides a solid-state device which improves upon the previous transpinnor design. More specifically, the present invention provides a transpinnor design in which operation of the transpinnor is based on current-induced magnetization reversal. Current-induced magnetization reversal is caused by current flowing through the thin-film structures themselves. This may be contrasted with field-induced reversal which is caused by current flowing through an associated conductor which is adjacent to but insulated from the thin film structures. Current-induced reversal may result from a number of mechanisms including, for example, spin torque exerted by a spin-polarized current (i.e., spin-transfer), current-induced domain-wall motion, and reversal by the current-generated Oersted (magnetic) fields. Thus, while specific embodiments of the invention are described with reference to spin transfer as the reversal or switching mechanism, it should be understood that embodiments in which other current-induced reversal mechanisms come into play are within the scope of the invention.

The improved transpinnor of the present invention may be employed to implement any-of the wide variety of “all-metal” circuits and systems which may be implemented using the transpinnor described in the above-referenced patents. It should be noted at the outset that the term “all-metal” as used herein refers to systems, circuits, and circuit components which do not employ semiconductor materials, but which may employ non-metallic insulating materials.

Specific embodiments of the improved transpinnor of the present invention differ from the previous transpinnor design in several respects. For example, in several embodiments, the current flow in the spin-transfer transpinnor elements of the present invention is perpendicular to the thin-film plane, i.e., CPP, rather than in the plane (CIP) as described above (and as described below the film structure for specific embodiments of the present invention can be MTJ as well as GMR). It should be noted that when making electrical connections in a CPP implementation, the wires connect perpendicular to (rather than parallel to) the plane of the film structures.

In addition, the magnetizations in the thin-film elements of the transpinnor of the present invention are switchable by a process known as current-induced magnetization reversal. That is, the switching occurs when sufficient current flows in the thin-film elements. As mentioned above, there are several possible mechanisms which can cause current-induced reversal. It should be noted that the terms “reversal” and “switching” are used interchangeably herein.

In embodiments in which the reversal mechanism is spin transfer, switching occurs when there is sufficient current flowing perpendicular to the plane of the thin-film elements. Spin-transfer switching is faster than magnetic field induced switching. The direction of switching-current flow determines the resistance (i.e., as determined by the relative alignments of magnetization vectors) of the elements. It should be noted however that, according to some embodiments, magnetic fields from striplines may still be employed in spin-transfer transpinnors to switch the magnetization or affect the current required for spin-transfer switching to take place.

According to different embodiments, the elements of which various embodiments of the transpinnor are constructed may comprise different types of thin-film structures. According to specific embodiments, structures employing either GMR films or magnetic tunnel junction (MTJ) films may be employed. These films—collectively referred to herein as quantum magnetoresistance (QMR) films—differ from each other in the nature of the nonmagnetic layers that separate the magnetic layers. GMR films employ metal layers while MTJ films employ insulators.

In addition, electron transport is different in these film types. Electrons in GMR films are transported by ordinary electric conduction, while those in MTJ films are transported by quantum tunneling. Additional information relating to the use of GMR films in current-induced switching is discussed by H. W. Schumacher and C. Chappert in Current-induced precessional magnetization reversal, Applied Physics Letters, Volume 83, Number 11, Sep. 15, 2003, the entire disclosure of which is incorporated herein by reference for all purposes. Information relating to the use of spin-transfer switching is discussed by the NIST group (http://www.boulder.nist.gov/div816/2002/Magnetodynamics/).

In both film types the change in element resistance arises from changes in the relative orientation of magnetization vectors associated with the different magnetic layers with parallel magnetizations corresponding to relatively low resistance and antiparallel magnetizations corresponding to relatively high resistance. MTJ films have been shown to exhibit higher proportional resistance changes than GMR films. Such high resistance changes improve practically all operating characteristics of a transpinnor. In any case, equations (1) and (2) above apply to both GMR and MTJ with the replacement of the term gmr by qmr in Eq. 2.

Switching times as short as 120 ps have been observed in CPP structures using spin-transfer switching. The high-frequency potential of this switching method is discussed by the NIST group: “Unlike devices that are based on charge transfer, whose frequency performance is limited by electron velocities and charge-transfer times, the electron spin has no fundamental frequency limitation . . . . Recent theoretical work has predicted that a spin-polarized direct current injected into a [nanoscale] magnetic structure can generate coherent precession of the magnetization [whose] precession frequency can be tuned from 1 GHz to 50 GHz.”

In the spin transfer mode, switching is induced by flooding a QMR film with spin-polarized electrons. These interact with the orbital electrons in the film, causing switching. The spin-polarized electrons are produced by running current through a magnetic film. When the current emerges, the electrons are polarized in the direction of the film magnetization, i.e. a majority of electron spins are oriented in the direction of the magnetization.

The dynamics of magnetization rotation is governed by the gyromagnetic equation; in Landau-Lifshitz form this is
dm/dt =−m×[γ H+β J m₀] (3)
where m is the magnetization in the layer being switched, H is an external magnetic field impressed on the layered film structure, J is the magnitude of the current flowing between layers, m₀ is a unit magnetization vector in the material providing the polarized current, γ is the gyromagnetic constant, and β is a parameter that encompasses properties of the electron and of the particular material. The Gilbert damping factor has been left out of this equation, as it does not bear on the following discussion; the expression with the damping factor included is given by X. Zhu and J-G Zhu in the Nonvolatile Memory Technology Symposium 2003, the entire disclosure of which is incorporated herein by reference for all purposes.

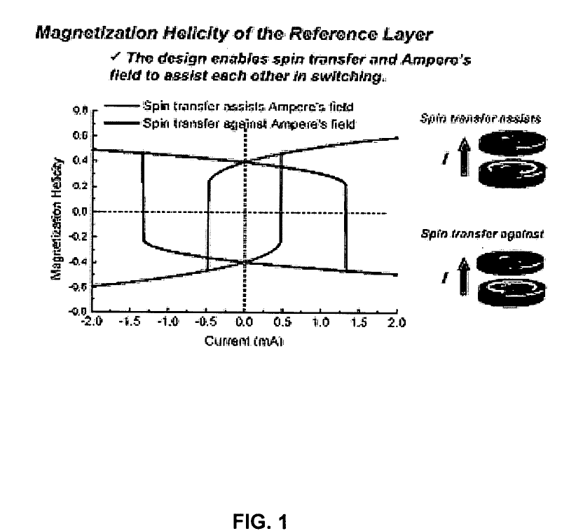

Equation (3) indicates that both the magnetic fields, H, and the spin-polarized currents, Jm₀, can cause the magnetization, m, in a magnetic material to rotate, i.e. can produce switching. Thus a transpinnor can be switched either by an applied field produced by current in one or more striplines, by current-induced magnetization reversal, or by a combination of the two. The possibility of using a combination of spin transfer and an applied field results in more flexibility and can lead to lower thresholds than switching by either mechanism alone. If the external field aids the spin transfer, the result is a lower threshold. If the external field opposes the spin transfer, the result is a higher threshold. This may be understood with reference to the graph of FIG. 1 (taken from the Zhu reference cited above) which illustrates that an external field from a conductor can either aid or oppose spin-transfer switching.

A magnetoresistive value of 230% was reported in an EE Times article by Yoshiko Hara dated Sep. 13, 2004 (entitled Japan Team Opens Path to Gbit MRAMs and incorporated herein by reference in its entirety), in a CPP structure fabricated at the National Institute of Advanced Industrial Science (Japan) and equipment maker Anelva Corp. This is more than an order of magnitude larger than that found in typical CIP structures based on GMR films. The improvement is due to the use of MgO instead of AlO for the insulating tunneling barrier. MgO has a lattice constant that closely matches that of the magnetic films and allows epitaxial growth that minimizes spin-independent scattering, and hence leads to higher QMR.

Such a large QMR value has far-reaching implications for transpinnor-based devices. For example, it has significant impact on the overall chip area and power consumption of all-metal magnetic RAM, also known as SpinRAM (see U.S. Pat. No. 5,237,529, U.S. Pat. No. 5,592,413, and U.S. Pat. No. 5,587,943, each of which is incorporated herein by reference in its entirety), which employs transpinnor electronics designed according to the present invention. The area of transpinnor support electronics decreases inversely as the square of qmr (decimal value of the QMR) and is an appreciable fraction of the memory array itself when based on previous CIP GMR designs. Thus, the use of high-QMR materials for the selection circuitry in SpinRAM has the potential for reducing its area by nearly two orders of magnitude. In other words, the overall chip area of the resulting SpinRAM chips will be effectively the area of the memory array itself.

Likewise, the power dissipated in a transpinnor goes nearly as the inverse square of qmr. Hence, an increase in qmr by an order of magnitude leads to a decrease by nearly two orders of magnitude of the power required to deliver the same output current. Finally, amplification (the ratio of the output current to the input current) is proportional to the qmr value. A transpinnor made from the film with qmr=2.3 is expected to exhibit significant amplification. Thus, use of transpinnors with large QMR values will lead to small chip sizes, highly efficient low-power devices, and large gain.

The choice of film structure to implement the transpinnor of the present invention may depend on the specific application. For example, in applications where switching speed is a primary consideration, e.g., in SpinRAM addressing circuitry (either write or read operation), MTJ structures may be more suitable. On the other hand, GMR CPP structures may be preferable for use wherever a small signal is to be sensed or a signal is to be amplified, e.g., in SpinRAM circuitry for sensing/amplifying the signal in the read operation. And as will be discussed, the present invention also contemplates the use of GMR CIP structures in which the magnetization reversal mechanism is current induced (as opposed to field induced). As mentioned above, transpinnors which employ current-induced reversal can switch by such mechanisms alone, or by such mechanisms in conjunction with an external field.

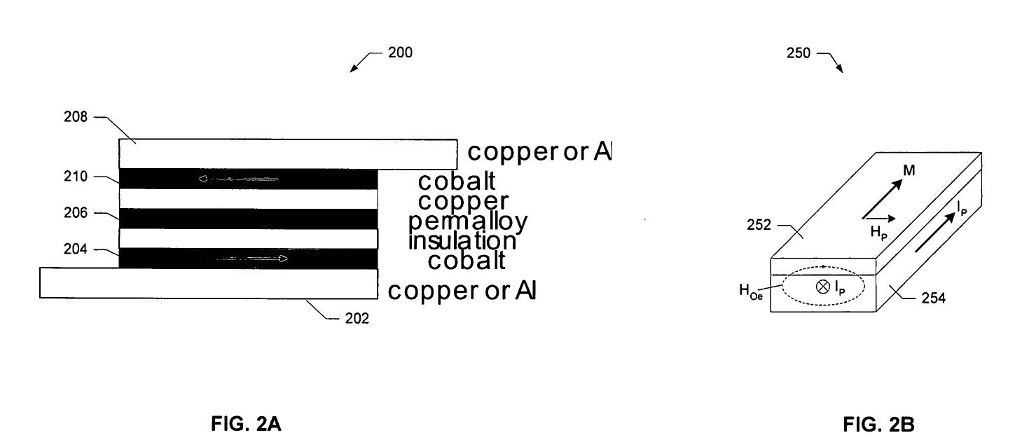

A cross section of an exemplary CPP MTJ structure which employs spin-transfer switching is shown in FIG. 2A. As will be discussed, multiple such structures configured in a transpinnor network results in a spin-transfer transpinnor. Electrons entering from the bottom conductor 202 are spin-polarized to the right as they emerge from the bottom cobalt layer 204. This magnetizes the permalloy layer 206 to the right. Likewise, electrons entering from the top conductor 208 are spin-polarized to the left as they emerge from the top cobalt layer 210. This magnetizes the permalloy layer 206 to the left. Thus the permalloy layer 206 can be magnetized in either direction depending on the direction of current flow.

As discussed above, the spin-transfer reversal mechanism is merely one of several current-induced reversal mechanisms which may be employed to implement a transpinnor according to various embodiments of the invention. Thus, it should be understood that the MTJ structure shown in FIG. 2A is only one example of the variety of structures which may be employed. For example, as mentioned elsewhere herein, CPP GMR structures may also be employed. As understood by one of ordinary skill in the art, such GMR structures do not include an insulator layer as shown in the MTJ structure of FIG. 2A, relying instead on conventional current conduction through the film rather than quantum tunneling.

According to one set of embodiments, current-induced magnetization reversal is effected in the GMR CIP structures of which a transpinnor is constructed. That is, embodiments are contemplated in which current-induced reversal is caused by current which is in the plane of the films of which the thin-film structures are constructed. A simplified representation of such a GMR CIP structure 250 is shown in FIG. 2B in which a current pulse Iₚ along the long device axis generates an Oersted field H_{Oe} resulting in a transverse field pulse Hₚ in the center of free layer 252 which is situated on top of spin-valve stack 254. Further information regarding such structures and the various mechanisms which cause magnetization reversal are described by Schumacher and Chappert, incorporated herein by reference above.

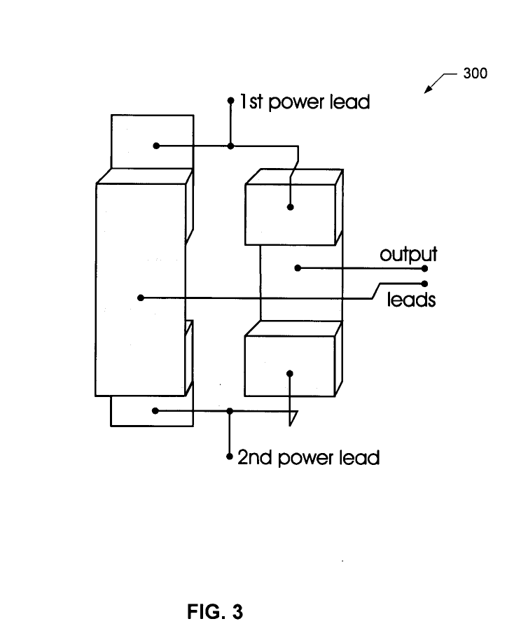

Referring once again to spin-transfer implementations, in spin-transfer switching, the current that switches each QMR element is perpendicular to the plane (CPP). Current that goes up (e.g., in FIG. 2A) switches the permalloy in one direction, and current that goes down switches the permalloy in the other direction. A spin-transfer transpinnor gives an output when its bridge configuration of QMR elements is unbalanced, e.g. when the QMR elements in the upper left and lower right corners are in one state and the QMR elements in the upper right and lower left are in the other. To create such an imbalance, the current should flow in one direction in the upper right and lower left and in the other direction in the upper left and lower right. This is illustrated by the exemplary transpinnor configuration shown in FIG. 3 which produces one logic state if the power current is positive and the other if the power current is negative.

Transpinnor 300 includes four QMR elements which may be of the kind shown in and described above with reference to FIGS. 2A and 2B. The current travels through each QMR element perpendicular to the planes of the thin-films of which they are constructed. A nonzero output signal occurs when the bridge configuration is resistively unbalanced, e.g., the top right and bottom left elements are in one state and top left and bottom right elements are in another. The transpinnor output can be switched by reversing the power current.

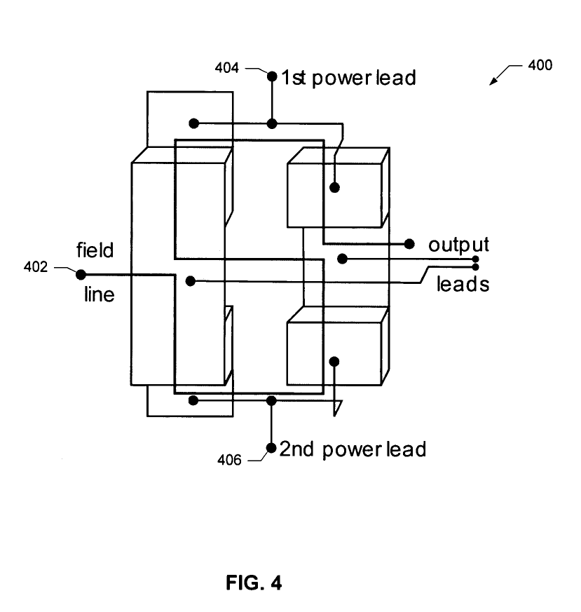

FIG. 4 shows a spin-transfer transpinnor 400 with both a field-line input (conductor 402) and a spin-transfer input (power leads 404 and 406). The combination is a very versatile and powerful device that can be switched very fast. That is, the combination of mechanisms which enable manipulation of element magnetizations enables spin-transfer transpinnor 400 to be used, for example, as a gate selected by coincident current as well as a variety of logic elements. In addition, the spin-transfer transpinnor can be further enhanced for logic functions by the incorporation of multiple field striplines carrying separate signals.

A transpinnor, whether based on CIP or CPP structures (either GMR or MTJ), may be configured to have operational characteristics similar to both transistors and transformers. Like a transistor, it can be used for amplification or logic. Unlike semiconductor transistors and like a transformer, the transpinnor input is DC isolated from the output. Unlike conventional transformers, a transpinnor has no low-frequency cutoff; the coupling is flat down to-and including DC. Transpinnors operate in a wide temperature range, spanning room temperature. Their operational characteristics (e.g., current requirements) tend to improve as their features shrink.

The myriad applications in which the transpinnor of the present invention may be employed may be understood with reference to the U.S. Patents incorporated by reference above, and several copending U.S. patent applications. That is, any of the circuits and systems in which earlier implementations of the transpinnor may be employed may also be implemented using the various embodiments of the transpinnor described herein. Some of these exemplary applications will be described below with reference to the remaining figures. It will be understood that reference to these applications is for exemplary purposes and should not be construed to limit the application to which the present invention applies.

As described in previous transpinnor patents incorporated by reference above, when biased in the appropriate operating region, transpinnors of the present invention can be used as basic building blocks of logic gates, thereby providing the foundation for digital electronics. While logic elements can be made with combinations of transpinnors, e.g., as with transistors, there is another alternative. That is, various logic operations (e.g., AND, OR, NAND, NOR, NOT, XOR, etc.) can be implemented with a single transpinnor.

In addition, transpinnors operating in the linear region can be used to develop a full complement of basic analog circuits sufficient to create general-purpose analog circuitry. A specific example of a transpinnor operating in the linear region for application to signal amplification is the differential amplifier, typically used to eliminate common-mode signal and common-mode noise within the frequency range of their operation. As mentioned above, the range of operation of the transpinnor in its transformer function extends from (and including) DC to the high-frequency cutoff limit. The transpinnor can therefore be utilized in its transformer function to remove common-mode signals in the differential-input mode, as well as in its transistor function to amplify a low signal in the single-ended output mode.

According to one application of the transpinnor of the present invention, a memory technology is provided which is based on such transpinnors in combination with magnetoresistive memory cells. One such memory array includes individual memory cells comprising thin film structures which store one or more bits of information in their magnetic layers. Memory access lines are configured to provide random access to each cell in the array. Selection matrices, control electronics, preamplifiers, and sense amplifiers are all implemented with transpinnors designed according to the various embodiments of the invention.

A further application provides a unified memory architecture in which each of a plurality of memory types in the architecture are implemented using such memory arrays. A specific example of such an architecture is a computer memory architecture in which both system memory and long term storage are implemented this way. In fact, embodiments of the invention may employ all-metal memory based on transpinnors and magnetoresistive memory cells to replace any memory in a conventional computing architecture, e.g., cache memory and flash memory, as well as any memory in any type of device architecture different from such conventional architectures, e.g., handheld device memory.

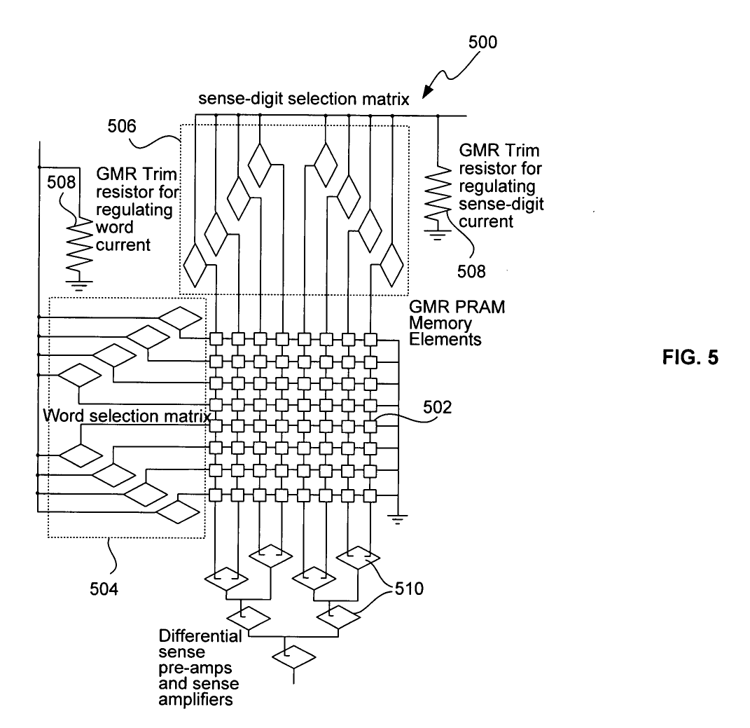

FIG. 5 is a simplified diagram of one such random access memory array 500, also referred to as a SpinRAM, the selection circuitry for which may be designed using the transpinnors of the present invention. For the sake of clarity, only 64 storage cells 502 have been shown. It will be understood, however, that the simplified architecture of FIG. 5 may be generalized to any size memory array desired. It should also be noted that the control lines for the selection electronics have been omitted for clarity. In this example, transpinnors are used to select the word lines to be activated (504), select the sense-digit and reference lines to be activated (506), regulate the voltage to the drive lines (508), amplify the difference in current between selected sense-digit and reference line pairs (510), and perform further sense amplification in successive stages.

Examples of storage cells which may be used to implement memory 500 are described in U.S. Pat. No. 5,587,943 and U.S. Pat. No. 6,594,174, the entire disclosures of both of which are incorporated herein by reference for all purposes. Additional details regarding the implementation of such a memory array and various applications thereof are provided in U.S. Pat. No. 6,483,740, the entire disclosure of which is incorporated herein by reference for all purposes.

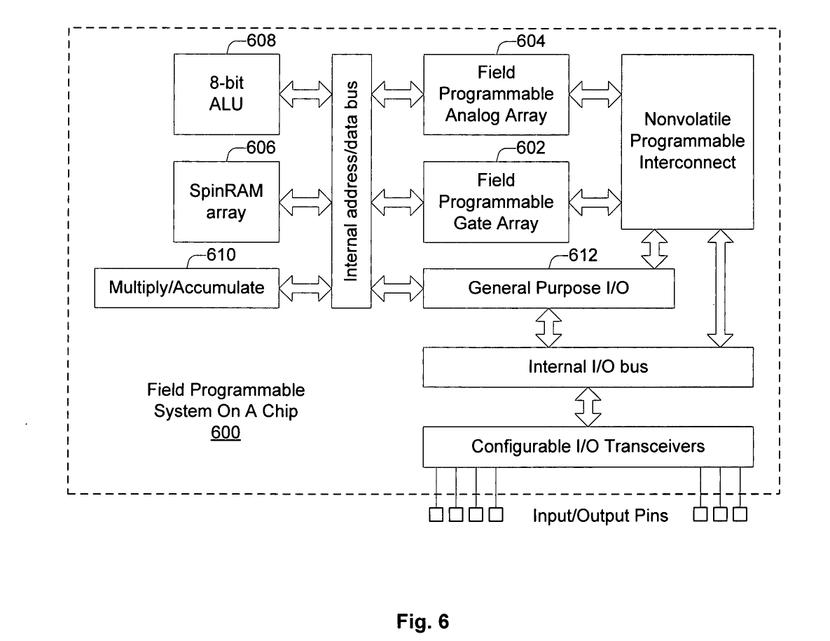

According to yet another application, a switch based on the transpinnor of the present invention is provided which may be used in any larger circuit in which a conventional switch might be employed, e.g., an FPGA. One or more such FPGAs may be included as part of a larger, field programmable system-on-a-chip (FPSOC). One such generalized implementation is shown in FIG. 6. According to various embodiments, any or all of the system components of FPSOC 600 may be based on QMR electronics. For example, FPGA 602 may be implemented using transpinnor switch matrices and transpinnor logic gates. Some or all of the mixed-signal components of field programmable analog array 604 (e.g., differential amplifiers, sample-and-hold circuits, etc.) may be implemented using transpinnor-based circuits. In addition, memory array 606 may be implemented as a SpinRAM array. Arithmetic logic unit 608, multiply/accumulate unit 610, and general purpose I/O 612 may all be implemented using transpinnor logic gates. Additional details on implementing a transpinnor as a switch and on implementing circuits and systems using such switches as well as other transpinnor circuits are provided in U.S. Pat. No. 6,573,713, the entire disclosure of which is incorporated herein by reference for all purposes.

Other exemplary applications for the transpinnor of the present invention include transmission line transceivers (as described in U.S. Pat. No. 6,859,063), interface circuits between “all-metal” electronics and semiconductor circuitry (as described in U.S. patent application Ser. No. 10/419,282), three-dimensional circuits (as described in U.S. patent application Ser. No. 10/731,732), circuits (e.g., display electronics) on a variety of rigid and flexible substrates (as described in U.S. patent application Ser. No. 10/806,895), and nonvolatile sequential machines (as described in U.S. patent application Ser. No. 10/935,914). The entire disclosure of each of these patents and patent applications is incorporated herein by reference for all purposes.

While the invention has been particularly shown and described with reference to specific embodiments thereof, it will be understood by those skilled in the art that changes in the form and details of the disclosed embodiments may be made without departing from the spirit or scope of the invention. In addition, although various advantages, aspects, and objects of the present invention have been discussed herein with reference to various embodiments, it will be understood that the scope of the invention should not be limited by reference to such advantages, aspects, and objects. Rather, the scope of the invention should be determined with reference to the appended claims.

1. A solid-state component comprising a network of multi-layer structures, each multi-layer structure exhibiting magnetoresistance and having magnetization vectors associated therewith which are operable to be switched at least in part by current-induced magnetization reversal, wherein the solid-state component generates an output signal when the network of multi-layer structures is resistively imbalanced, the output signal corresponding to output nodes in the network and being a function of an input signal applied at input nodes in the network.

2. The solid-state component of claim 1 wherein each multi-layer structure exhibits giant magnetoresistance.

3. The solid-state component of claim 2 wherein each multi-layer structure comprises at least one period of alternating magnetic material and non-magnetic material.

4. The solid-state component of claim 3 wherein the at least one period comprises a cobalt layer, a conductive layer, and a permalloy layer.

5. The solid-state component of claim 1 wherein each multi-layer structure comprises a magnetic tunnel junction (MTJ) structure.

6. The solid-state component of claim 5 wherein each MTJ structure comprises at least one period of alternating magnetic material and non-magnetic material.

7. The solid-state component of claim 6 wherein the at least one period comprises a first cobalt layer, an insulating layer, a permalloy layer, a conductive layer, and a second cobalt layer.

8. The solid-state component of claim 1 wherein the input signal comprises an input current normal to thin films in each of the multi-layer structures.

9. The solid-state component of claim 1 wherein the input signal comprises an input current in the plane of thin films in each of the multi-layer structures.

10. The solid-state component of claim 1 further comprising a conductor coupled to at least one of the multi-layer structures which is operable to apply a first magnetic field to the at least one of the multi-layer structures, thereby further facilitating switching of the magnetization vectors using field-induced magnetization reversal.

11. The solid-state component of claim 1 wherein each multi-layer structure has a first and second magnetization vectors associated therewith, the first and second magnetization vectors associated with each multi-layer structure having an orientation relative to each other, and wherein switching of the magnetization vectors comprises changing the orientation between the first and second magnetization vectors in selected ones of the multi-layer structures.

12. The solid-state component of claim 11 wherein changing the orientation comprises changing the orientation from a parallel relationship to an anti-parallel relationship.

13. The solid-state component of claim 1 wherein the network comprises four multi-layer structures configured in a bridge network, the input nodes comprising first and second opposing nodes of the bridge network, and the output nodes comprising third and fourth opposing nodes of the bridge network.

14. The solid-state component of claim 13 wherein at least partial switching of the magnetization vectors is achieved by application of an input current between the input nodes.

15. The solid-state component of claim 14 further comprising a conductor coupled to at least one of the multi-layer structures which is operable to apply a first magnetic field to the at least one of the multi-layer structures, thereby further facilitating the switching of the magnetization vectors associated with the at least one of the multi-layer structures.

16. A circuit comprising a plurality of the solid-state components of claim 1.

17. The circuit of claim 16 wherein the plurality of solid-state components are configured as a plurality of different circuit component types.

18. The circuit of claim 16 further comprising a plurality of memory cells operation of which relies on a magnetoresistive effect.

19. An electronic system comprising the circuit of claim 16.

20. The solid-state component of claim 1 wherein the multilayer structures comprise at least one of GMR structures, MTJ structures, CIP structures, and CPP structures.

21. The solid-state component of claim 1 wherein the current-based magnetization reversal is caused by at least one of spin torque exerted by a spin-polarized current, current-induced domain-wall motion, and reversal by current-generated Oersted fields.

22. A solid-state component comprising a plurality of multi-layer structures configured in a bridge network, first and second opposing nodes of the network comprising an input, and third and fourth opposing nodes of the network comprising an output, each of the multi-layer structures exhibiting magnetoresistance and being operable to have associated magnetization vectors at least partially switched by spin-transfer switching in response to current applied via the input, the current being perpendicular to the layers of the multi-layer structures, wherein the solid-state component generates an output signal at the output when the network of multi-layer structures is resistively imbalanced, the output signal being representative of the current applied at the input.
